(19) United States
(12) Patent Application Publication
(10) Pub. No.: US 2004/0155312 A1
(43) Pub. Date: Aug. 12, 2004

(54) Optical element, especially an eye implant

(76) Inventor: Wolfgang Muller-Lierheim, Munchen (DE)

Correspondence Address: OSTROLENK FABER GERB & SOFFEN, 1180 AVENUE OF THE AMERICAS, NEW YORK, NY, 100368403

(21) Appl. No.: 10/481,780

(22) PCT Filed: Jun. 20, 2002
(86) PCT No.: PCT/EP02/06854

(30) Foreign Application Priority Data
Jun. 20, 2001 (DE) 101 29 787.4

(51) Int. Cl. H01L 31/00

(52) U.S. Cl. 257/449

(57) ABSTRACT

An optical component, in particular an eye implant of a transparent material, to which there is added at least one transparent filler having a higher refractive index than that of the component material and of a particle size at which substantially no light scatter occurs in the component material.

The invention concerns an optical component comprising a transparent material, in particular an eye implant, for example an intraocular lens.

### STATE OF THE ART

In the case of optical components which are used in particular as eye implants such as intraocular lenses and the like, the endeavour is to achieve small geometrical dimensions so that the cut required for the implantation procedure can be kept small. If the implant is to be used as an intraocular lens in the optical system of the eye, it is necessary, for that purpose, to achieve the highest possible refractive index of the material of the component, for example by a high electron density for the material. In addition the implant material must be biologically compatible. Various polymers, polymethylmethacrylate and hydrogels such as HEMA, and silicones, are known for that purpose.

The foldable eye implants which are available at the present time, in particular intraocular lenses, by virtue of their center thickness however, still require a cut of about 3 mm long in the implantation procedure.

### OBJECT OF THE INVENTION

Therefore the object of the invention is to provide an optical component, in particular an eye implant, which by virtue of its increased refractive index can be produced with a reduced thickness, that is to say small geometrical dimensions, in the direction of the optical beam path.

In accordance with the invention that object is attained in that added to the transparent material of the optical component, in particular an eye implant, is a substantially transparent filler with a higher refractive index than that of the surrounding material of the component and of a particle size at which substantially no light scatter occurs in the component material.

The optically clear or transparent filler enjoys a high electron density which affords an increased refractive index. That high electron density can be achieved by oxides which are difficult to dissolve, with a highly charged cation, for example by heavy metal, in particular lead and bismuth compounds. Those heavy metal compounds are present in crystalline, in particular nanocrystallinely deposited form, for example as silicates, germanates, aluminates or titanates. The heavy metals are fixedly integrated in the crystal matrix and are not dissolved out in the biological medium of the eye. Therefore the fillers do not adversely affect the biological compatibility of the transparent component material or implant material in which they are distributed in finely divided particle form, in particular in the form of nanoparticles.

A filler which is preferably used is rutile (TiO₂). That filler is compatible with the body and biocompatible. It is inert and difficult to dissolve, thermally stable and thus autoclavable. It is also available inexpensively in relatively large amounts. That filler can be deposited in nanocrystalline form and can thus be technically produced in a particle size in respect of which practically no light scatter is caused in the component material. In addition rutile has a relatively high refractive index (nₘₑₐₙ=2.7; nₒ=2.616; nₑ=2.903 in Na-light).

When using 20% by volume of rutile as filler in an acrylate with a refractive index of n=1.5, the refractive index of the acrylate can be increased by the filler to about 1.78. When using 20% by volume of rutile in silicone rubber with a refractive index of n=1.43, the refractive index of the optical material of silicone rubber can be increased to about 1.68. In that way it is possible to increase the effective difference in refractive index for example of a foldable implanted intraocular lens in the surrounding chamber humor by the factor of between 2 and 2.5. In that way it is possible to produce the foldable intraocular lenses in a reduced thickness and with an improved folding capability.

In addition optical components can be produced with a differing filler content in various zones of the component. That gives chemically homogeneous components with zones involving differing refractive indices. By way of example it is possible in that way to produce bifocal or multifocal lenses. The transition between regions involving differing refractive indices is not endangered by breakage. The surface in the case of in particular bifocal or multifocal lenses can involve a homogeneous configuration, in particular a homogeneous curvature.

When birefringent fillers are polymerised in, they can be oriented for example in an electrical field or a magnetic field. In that way it is possible to produce an optical component which has differing refractive indices for differently polarised light.

The optical component can be in the form of a medical product or part of a medical product. The optical component can thus be for example a spectacles lens, a contact lens for vision correction of an eye, a constituent part of an endoscope optical system or an eye implant, in particular an intraocular lens.

Conventional procedures such as injection molding, a cutting procedure or the like can be used when shaping the optical component, in particular an eye implant.

In the shaping production process, for example by injection molding, further improved dimensional accuracy is achieved as a consequence of the fillers.

1. An optical component comprising a transparent component material, characterised in that added to the component material is at least one transparent filler having a higher refractive index than that of the surrounding component material and of a particle size at which substantially no light scatter occurs in the component element.

2. An optical component as set forth in claim 1 characterised in that the filler is an oxide which is difficult to dissolve.

3. An optical component as set forth in claim 1 or claim 2 characterised in that the filler is a silicate, a germanate, aluminate or titanate.

4. An optical component as set forth in one of claims 1 through 3 characterised in that the filler is a crystalline form of a heavy metal compound.

5. An optical component as set forth in one of claims 1 through 4 characterised in that it is in the form of a medical product.

6. An optical component as set forth in one of claims 1 through 5 characterised in that the component material has zones of differing filler content for producing zones of a different refractive index.

7. An optical component as set forth in claim 6 characterised in that the component is in the form of a bifocal or multifocal lens.

8. An optical component as set forth in one of claims 1 through 7 characterised in that the filler is rutile (TiO₂).

9. An optical component as set forth in claim 1 characterised in that the filler has a highly charged cation proportion.

10. An optical component as set forth in one of claims 1 through 9 characterised in that the component material is an acrylate or silicone rubber.
